(19) United States
(12) Patent Application Publication
(10) Pub. No.: US 2026/0347633 A1
(43) Pub. Date: Nov. 5, 2026

(54) PHOSPHOR COMPOSITIONS AND ASSOCIATED SYSTEMS, DEVICES AND METHODS

(71) Applicant: UbiQD, Inc., Los Alamos, NM (US)

(72) Inventors: Daniel McCray Kroupa, Kirkland, WA (US); Jared Scott Silvia, Kirkland, WA (US); Nicholas Charles Anderson, Kirkland, WA (US); Sarah Blakeslee Little, Kirkland, WA (US); Wylie Fu-Xing Kau, Kirkland, WA (US)

(21) Appl. No.: 19/120,367

(22) PCT Filed: Oct. 6, 2023
(86) PCT No.: PCT/US2023/076290

§ 371 Date: Apr. 11, 2025

Related U.S. Application Data
(60) Provisional application No. 63/379,136, filed on Oct. 11, 2022.

(51) Int. Cl. C09D 11/50; C08K 3/013; C09D 5/22; C09D 7/61; C09D 11/037

(52) U.S. Cl. CPC C09D 11/50; C09D 5/22; C09D 7/61; C09D 11/037; C08K 3/013

(57) ABSTRACT

Phosphor compositions and associated systems, devices, and methods are disclosed herein. Exemplary phosphor compositions can comprise a chemical formula of one of M:ABX₃, M:AB₂X₅, M:A₄BX₆, M:C₂DX₅, or M:A₂CDX₆, M:AgCDX₁₂, or M:A₂C₂D₂X₁₀, wherein A, B, C, D, and M are cations, and X is an anion. “A” comprises lithium (Li⁺), sodium (Na⁺), potassium (K⁺), rubidium (Rb⁺), caesium (Cs⁺), methylammonium, formamidinium, guanidinium, or mixtures thereof, and “M” comprises yttrium (Y³⁺), Lanthanum (La³⁺), cerium (Ce³⁺), praseodymium (Pr³⁺), neodymium (Nd³⁺), promethium (Pm³⁺), samarium (Sm³⁺), europium (Eu³⁺), gadolinium (Gd³⁺), terbium (Tb³⁺), dysprosium (Dy³⁺), holmium (Ho³⁺), erbium (Er³⁺), thulium (Tm³⁺), ytterbium (Yb³⁺), lutetium (Lu³⁺), scandium (Sc³⁺), iron (Fe³⁺), aluminum (Al³⁺), vanadium (V²⁺), chromium (Cr²⁺), manganese (Mn²⁺), bismuth (Bi³⁺) or mixtures thereof.

### CROSS-REFERENCE TO RELATED APPLICATIONS

The present application claims priority to U.S. Provisional Patent App. No. 63/379,136, filed Oct. 11 2023, the disclosure of which is incorporated herein by reference in entirety.

### TECHNICAL FIELD

The present disclosure relates to phosphor compositions and associated systems, devices and methods. In some embodiments, the phosphor compositions are used as unique identifiers to authenticate an object the phosphor composition is disposed on or embedded in.

### BACKGROUND

Fraudulent or counterfeit goods exact a high cost on the global economy. According to estimates by international agencies, counterfeit goods account for 2-7% of global trade, or $ 200-600 billion worth of goods every year. As a result, governments and businesses around the world are in an arms race with counterfeiters, and must regularly develop innovative technology to stay ahead of them.

There are four levels of security commonly referenced in the industry. Level 1 security includes overt features, such as tamper-evident labels, holograms, watermarks, or tactile relief patterns detectable by the bare human senses (e.g., sight, touch, and smell). Level 2 security includes covert features using ordinary devices, such as embedded microchips (e.g., radio frequency identification (RFID) chips) that can be read by a mobile phone or luminescent pigments that glow under a UV light source. Level 3 security includes covert security features using special/sophisticated devices, such as security fibrils or filaments embedded into a material that can be identified using dedicated detectors. Level 4 security features involve forensics, taggants, and laboratory testing, such as micro-or nano-patterned textures and/or marks that require high-resolution microscopes for detection (e.g., electron microscopy), as well as taggants with specific chemical compositions that require forensic elemental analysis (e.g., X-ray fluorescence, mass spectroscopy, nuclear magnetic resonance (NMR) spectroscopy for detection.

Luminescent security inks are highly versatile and can serve as Level 1, 2, 3, or 4 security marks depending on the sophistication of their design and application. Luminescent security inks for authentication are known in the art in some cases, as documented by Rajchman et. al. in U.S. Pat. No. 2,742,631 titled “Methods for recording and transmitting information using phosphors” and Berler in U.S. Pat. No. 3,614,430 titled “Fluorescent-ink-imprinted coded document and method and apparatus for use in connection therewith.” The methods in these patents proposed using spectral signatures of organic dyes and/or inorganic phosphors as security inks for authentication (i.e., Security Levels 1 and 2). Further advances in the art include the use of semiconductor nanocrystals or quantum dots, as described by Barbara-Guillem in U.S. Pat. No. 6,576,155 titled “Fluorescent ink compositions comprising functionalized fluorescent nanocrystals”, McGrew in U.S. Pat. No. 6,692,031 titled “Quantum dot security device and method”, and McDaniel in U.S. Pat. No. 9,382,432 titled “Quantum dot security inks”. These patents teach the improvement in light conversion efficiency of quantum dots versus organic dyes as well as the use of time-resolved photoluminescence (PL) lifetimes as a detectable security feature (Security levels 1, 2, and 3). More recently, Kovalenko et. al. proposed the use of metal halide semiconductor nanocrystals (e.g., perovskite nanocrystals) as luminescent security tags in Nat. Communications paper “Radiative lifetime-encoded unicolor security tags using perovskite nanocrystals”.

The current generation of security inks have drawbacks that limit their utility. First, most security inks that use organic dyes or inorganic phosphors have limited durability, poor light conversion efficiency, and/or very fast photoluminescence lifetimes. Second, most security inks based on quantum dots or nanocrystals either absorb or emit visible light, which limits their utility as a covert mark. Additionally, most quantum dots have a small Stokes shift (e.g., less than 50 nm) such that the emitted light overlaps with the absorption, which limits light outcoupling. Furthermore, the most common quantum dots based on CdE, PbE, CuInZnE, InP, and CsPbX3 (E=S, Se, Te; X=Cl, Br, I) contain toxic and/or carcinogenic ions which make them highly hazardous for commercial products. Synthetic methods for preparing and purifying quantum dots typically involve expensive reagents and solvents, rendering them expensive with respect to inorganic phosphors and organic dyes.

### BRIEF DESCRIPTION OF THE DRAWINGS

The patent or application file contains at least one drawing executed in color. Copies of this patent or patent application publication with color drawing(s) will be provided by the U.S. Patent & Trademark Office upon request and payment of the necessary fee.

Features, aspects, and advantages of the presently disclosed technology may be better understood with regard to the following drawings.

FIG. 1 is a schematic illustration of a system for creating a composite comprising a phosphor, in accordance with embodiments of the present technology.

FIG. 2 is a schematic illustration of a system for creating a substrate comprising a phosphor, in accordance with embodiments of the present technology.

FIGS. 3 and 4 are schematic illustrations of systems for detecting emitted light from a target, in accordance with embodiments of the present technology.

FIG. 5 is a flow chart for authenticating a target, in accordance with embodiments of the present technology.

FIG. 6A is plot illustrating photoluminescence excitation (PLE) spectra and corresponding photoluminescence (PL) spectra for different phosphor compositions, in accordance with embodiments of the present technology.

FIG. 6B is a plot illustrating PL spectra of different light emitting materials that include phosphors and dyes, in accordance with embodiments of the present technology.

FIG. 7 is a plot illustrating PL decays of the phosphor compositions of FIG. 6A, in accordance with embodiments of the present technology.

FIG. 8A is a dark-field image of a phosphor composition and FIG. 8B is a PL image of the phosphor composition of FIG. 8A, in accordance with embodiments of the present technology.

FIGS. 9A-9C illustrate visualizations of a phosphor composition under different illuminations, in accordance with embodiments of the present technology.

FIG. 10 is a plot illustrating PL spectra of phosphor compositions including different dopants, in accordance with embodiments of the present technology.

FIG. 11A is a scanning electron microscope (SEM) image of a phosphor composition without a protective shell, in accordance with embodiments of the present technology.

FIG. 11B is a tunneling electron microscope (TEM) image of a single phosphor with a 50-nanometer protective shell and FIG. 11C is a portion of the TEM image of FIG. 11B, in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

### I. Overview

As noted above, security inks that exist today have drawbacks that limit their utility and use in the market. These drawbacks include (i) the limited durability, poor light conversion efficiency, and very fast PL lifetimes of the security inks, (ii) the visible light that most security inks absorb or emit, which limits their utility as a covert mark undetectable by the naked eye, and (iii) the overlapping absorption and emission spectra and/or small Stokes Shift that limits light outcoupling, thus making the security ink less effective and more difficult to authenticate.

Embodiments of the present technology attempt to address at least some of these deficiencies of the conventional technologies, by disclosing phosphors that have improved light conversion efficiency, relatively slow PL lifetimes, and relatively large effective Stokes Shifts that enable better light outcoupling and better detection for authentication purposes. As disclosed herein, phosphors of the present technology possess characteristically strong light absorption properties, and the ability to tune the onset of light absorption from 300-1000 nm, e.g., by changing the ratio of halide ions. Doing so enables embodiments of the present technology to utilize a variety of low-cost, off-the-shelf light sources to photoexcite the phosphors in a custom optical detection system. In some embodiments, the luminescent species can be Yb³⁺ dopant ions that exhibit characteristic f-f orbital luminescence in the near-infrared (NIR) spectrum around 980 nm, which is invisible to the naked human eye and thus enables covert security marking applications. Similarly, other dopant ions that exhibit luminescence in the NIR spectrum (e.g., Nd³⁺ and Tm³⁺), can be the luminescent species in some embodiments. The light-conversion process of phosphors of the present technology has exhibited photon conversion as high as 95%, and the NIR photoluminescence lifetime is tunable based on composition, e.g., to a millisecond (ms) timescale. These and other properties of the phosphors of the present technology enable low-cost and effective photoluminescence detection schemes and data acquisition.

### II. Phosphor Compositions and Associated Systems, Devices and Methods

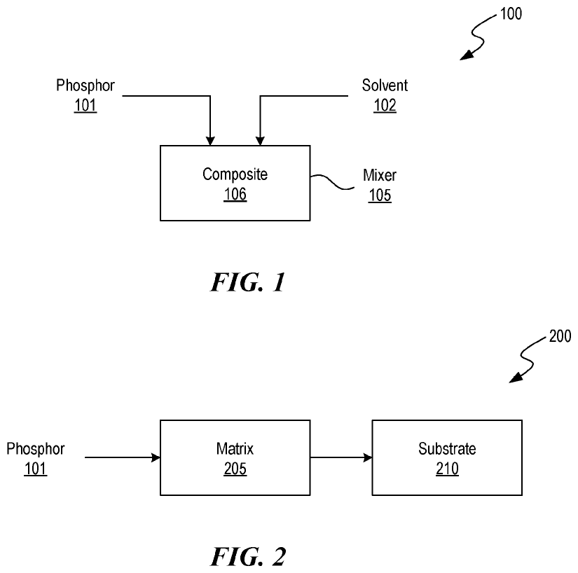

FIG. 1 is a schematic illustration of a system 100 for creating a composite comprising a phosphor, in accordance with embodiments of the present technology. The system 100 includes a mixer 105 configured to receive a phosphor 101 (e.g., a phosphor composition or first composition) and a solvent 102 (e.g., a second composition). The mixer 105 can mix the phosphor 101 and the solvent 102 to form a composite 106. The solvent 102 can comprise a polymer liquid poly(methylmetacrylate) (PMMA), PMMA in a toluene solution, polystyrene (PS), polyvinyltoluene (PVT), ethylene vinyl acetate (EVA) and/or poly(dimethylsiloxane) (PDMS). The composite 106 can be (or be further processed to become) a colloid, a printed ink, a thread, a band, a bead, or a suspension. After mixing the phosphor 101 and substrate 102, the composite 106 can be further treated (e.g., heated, annealed, cured, and/or activated with light and/or heat). For example, it has been shown that annealing the phosphor 101 can activate and/or optimize the NIR light conversion process.

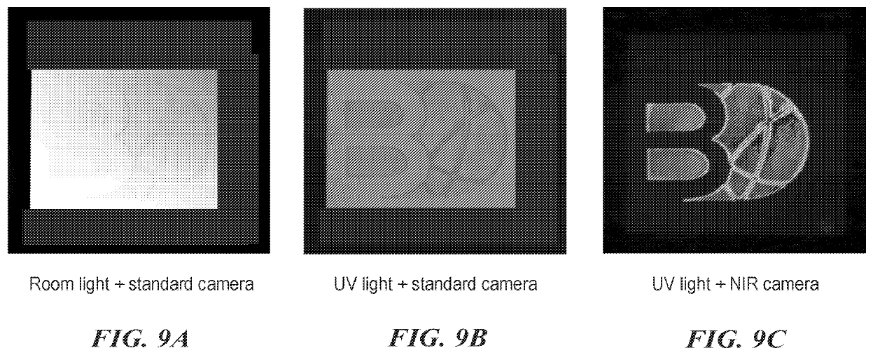

As described elsewhere herein, the composite 106 can be configured to be manipulated into a desired pattern, e.g., via processes including 2-dimensional (2D) printing, 3D printing, inkjet printing, screen printing, intaglio printing, stamping, spraying, spin coating, and/or extruding. The composite 106 can be transferred to a target (to be authenticated) via one or more of these processes. As an example, the composite 106 can be an ink comprising phosphor, PMMA, and toluene, which is stamped onto a target (e.g., a cotton paper) using a patterned rubber stamp (as shown in FIGS. 9A-9C). Once the ink dries and/or toluene evaporates, the phosphor is embedded in the PMMA matrix on the target.

The phosphor 101 can comprise a chemical formula of one of M:ABX₃, M:AB₂X₅, M:A₄BX₆, M:C₂DX₅, or M:A₂CDX₆, M:A₈CDX₁₂, M:A₂C₂D₂X₁₀, wherein: (i) A is a cation comprising lithium (Li⁺), sodium (Na⁺), potassium (K⁺), rubidium (Rb⁺), caesium (Cs⁺), methylammonium, formamidinium, guanidinium, or mixtures thereof, (ii) B is a cation comprising lead (Pb²⁺), tin (Sn²⁺), germanium (Ge²⁺), cadmium (Cd²⁺), magnesium (Mg²⁺), titanium (Ti²⁺), mercury (Hg²⁺) or mixtures thereof, (iii) C is a cation comprising silver (Ag⁺), copper (Cu⁺), tin (Sn⁺), sodium (Na⁺), potassium (K⁺), thallium (Tl⁺), gold (Au⁺) or mixtures thereof, (iv) D is a cation comprising indium (In³⁺), bismuth (Bi³⁺), antimony (Sb³⁺), gold (Au³⁺), thallium (Tl³⁺) or mixtures thereof, (v) X is an anion comprising oxygen (O₂₋), sulfur (S²⁻), Selenium (Se²⁻), tellurium (Te²⁻), fluorine (F⁻), chlorine (Cl⁻), bromine (Br⁻), iodine (I⁻), cyanide (CN⁻) or mixtures thereof, and (vi) M is a cation comprising yttrium (Y³⁺), Lanthanum (La³⁺), cerium (Ce³⁺), praseodymium (Pr³⁺), neodymium (Nd³⁺), promethium (Pm³⁺), samarium (Sm³⁺), europium (Eu³⁺), gadolinium (Gd³⁺), terbium (Tb³⁺), dysprosium (Dy³⁺), holmium (Ho³⁺), erbium (Er³⁺), thulium (Tm³⁺), ytterbium (Yb³⁺), lutetium (Lu³⁺), scandium (Sc³⁺), iron (Fe³⁺), aluminum (Al³⁺), vanadium (V²⁺), chromium (Cr²⁺), manganese (Mn²⁺), bismuth (Bi³⁺) or mixtures thereof. As n few examples, phosphors of the present technology can comprise M:ABX₃, M:A₂CDX₆, M:CsPbX₃, MCs₂AgBiX₆, or MCS₂Ag₁₋ₓNaₓBi_{1-y}In_{y}X₆. As another example, phosphors of the present technology can comprise a Yb³⁺-doped CsPb(Cl₁₋ₓBrₓ)₃ phosphor powder. As explained herein, such a powder can be integrated into inks and polymer precursors for printing and casting into composite security marks that retain the photoluminescence properties (e.g., excitation spectrum, emission spectrum, quantum yield, and lifetime) of the starting phosphor powder. In some embodiments, the photoluminescence properties of the phosphor composites do not degrade for at least 2, 4, 6, 8, 10, 12 or 14 days under ambient conditions.

The phosphor 101 can be a powder, a film, a coating, a pellet, a bead, nanocrystals, or microcrystals. In embodiments wherein the phosphor 101 comprises a powder, the phosphor 101 can have a mean particle diameter of 1 nanometer (nm)-100 micrometers (μm), or any value therebetween (e.g., 100 nm, 40 μm, 97 μm, etc.). In some embodiments, the phosphor 101 is altered such that the phosphor 101 has a desired mean particle diameter, e.g., by sieving, grinding, milling, melting, and/or centrifuging the phosphor 101 to form the desired mean particle diameter, and/or based on a desired application or end use.

In some embodiments, phosphors are conformally coated with a barrier coating, such as a metal-oxide coating, to improve various properties of the phosphor including, but not limited to, emission brightness, photoluminescence (PLQY), and durability. The barrier coating can comprise silicon dioxide (SiO₂), aluminum dioxide (Al₂O₃), titanium dioxide (TiO₂), and/or hafnium dioxide or hafnium (IV) oxide (HfO₂). In some embodiments, the barrier coatings comprise multiple layers of these materials (e.g., Al2O₃/TiO₂). The barrier coatings can improve the stability of the phosphors towards environmental degradation (e.g., from water and oxygen exposure), and multi-layer coatings can provide enhanced stability. The barrier coating(s) can be deposited onto a phosphor particle using chemical vapor deposition (CVD) techniques such as atomic layer deposition (ALD).

The phosphor 101 can be amorphous, crystalline, or semicrystalline. For those embodiments in which the phosphor 101 comprises a crystalline lattice, the M can be a dopant of the crystalline lattice and/or M can substitute for B or D in the crystalline lattice or on the crystalline surface. Additionally or alternatively, in some embodiments, M comprises no more than 49% of a molar ratio of M/(B+M) or M/(D+M).

In operation, the phosphor 101, when exposed to light (e.g., a pulsed light) from a light source, can be tailored to absorb light having a wavelength of 250-700 nm and/or emit light or electromagnetic radiation undetectable by the human eye. In some embodiments, when exposed to the light from the light source, the phosphor 101 emits electromagnetic radiation having a lower energy than that of the light source. Additionally or alternatively, the phosphor 101 may only emit electromagnetic radiation from a portion of the phosphor 101, and or different portions of the phosphor 101 may emit electromagnetic radiation at different wavelengths. For example, in such embodiments, a first portion of the phosphor 101 may emit electromagnetic radiation in response to light at a first predetermined wavelength and a second portion of the phosphor 101 different than the first portion may emit electromagnetic radiation at a second predetermined wavelength different than the first predetermined wavelength. The electromagnetic radiation emitted from the phosphor 101 in response to the light can be due to band-edge recombination and/or dopant emission.

The phosphor 101 can have an absorption maxima that does not overlap its emission maxima. For example, the difference between the absorption maxima and the emission maxima can be at least 50 nanometers (nm), 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1000 nm, 1050 nm, 1100 nm, 1150 nm, 1200 nm, or 1250 nm. Stated differently, the phosphor 101 can have a Stokes Shift of at least 50 nanometers (nm), 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1000 nm, 1050 nm, 1100 nm, 1150 nm, 1200 nm, or 1250 nm. The lack of overlap and/or a larger Stokes shift enables more light to be detected by the light detector(s). Additionally or alternatively, a larger Stokes Shift can also enable the PL of a phosphor to not be detected by the human eye, which can generally only view wavelengths within the range of 400-700 nm. As a result, phosphors of the present technology can be covert in that light absorbed or emitted therefrom is not visible to the naked eye.

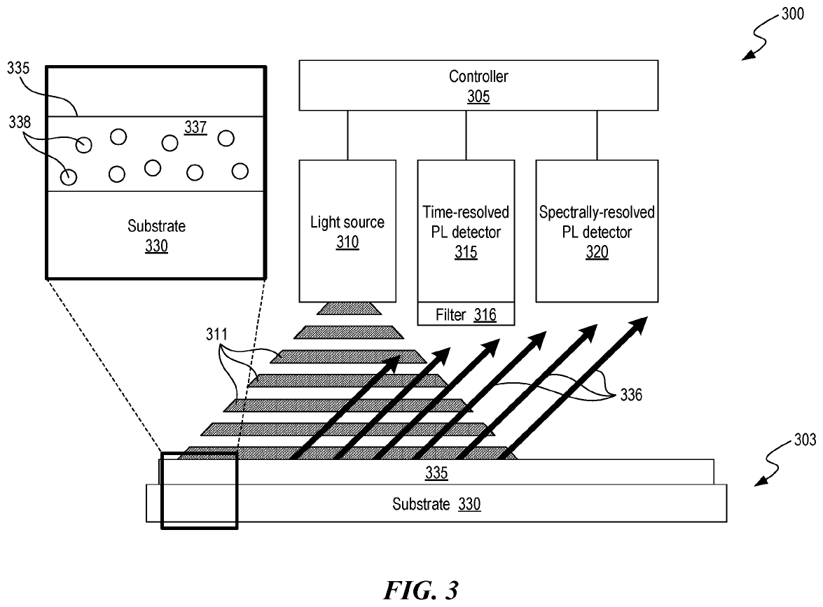

FIG. 2 is a schematic illustration of a system 200 for creating a substrate 210 comprising a phosphor, in accordance with embodiments of the present technology. As shown in FIG. 2, the phosphor 101 described with reference to FIG. 1 is combined with and/or embedded in a matrix 205, which can then be further processed with (e.g., woven into) another matrix to form a substate 210. For example, the matrix 205 can comprise a polymer, PMMA, PS, and/or PDMS. The substrate 210 can be a paper with the matrix 205 woven therein, or any other object that the matrix 205 can be attached to or embedded within.

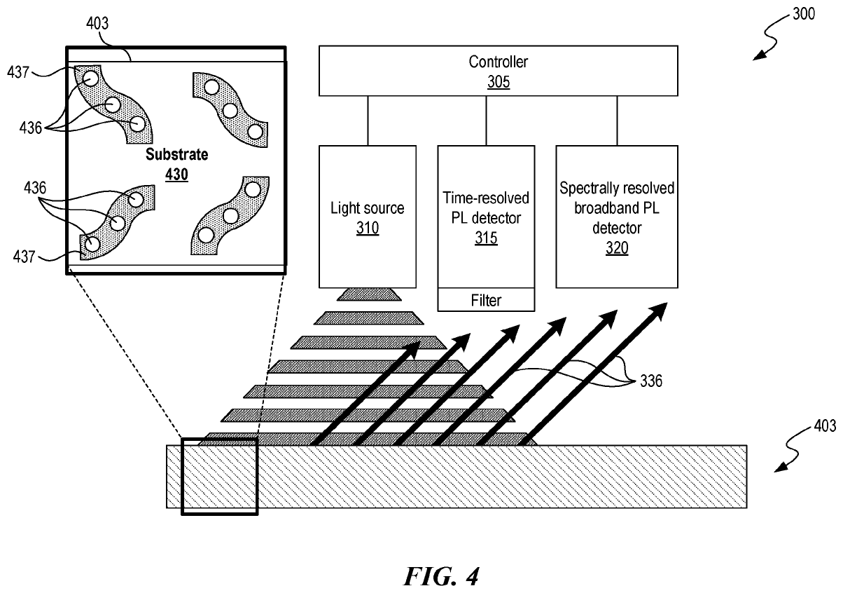

FIG. 3 is a schematic illustration of a system 300 for detecting emitted light from a target 303, in accordance with embodiments of the present technology. The target 303 includes a substate 330 and a composite 335 (e.g., the composite 106; FIG. 1) disposed over the substrate 330. The composite 335 can include a matrix or solvent 337 (e.g., the solvent 102; FIG. 1), and a phosphor 338 (e.g., the phosphor 101; FIGS. 1 and 2) mixed with or embedded in the solvent 102.

The system 300 includes a controller 305, and components electrically coupled to (e.g., in communication with) and controllable by the controller 305. The components can include a light source 310 configured to be positioned over and emit light 311 toward the target 303, and one or more light detectors configured to detect electromagnetic radiation emanated from the target 303 in response to the emitted light 311 from the light source 310. The one or more light detectors can include a time-resolved photoluminescence (TRPL) detector 315 configured to measure TRPL, and/or a spectrally-resolved broadband PL (SRPL) detector 320 configured to measure SRPL. In some embodiments, the system 300 only includes one of the TRPL detector 315 or SRPL detector 320 (i.e., one of the TRPL detector 315 or SRPL detector 320 is omitted). As shown in FIG. 3, the system 300 can further include a filter 316 coupled to the TRPL detector 315 and configured to inhibit particular wavelengths of light from being detected by the TRPL detector 315 and/or obtained by the controller 305.

The light source 310 is configured to emit light 311 toward the target 303. As shown in FIG. 3, the light 311 from the light source 310 can be pulsed (e.g., turned on and off quickly) to ensure the emission, light, or electromagnetic radiation 336 (“electromagnetic radiation 336”) emanated from the target 303 or composite 335 can be detected without extra light interference, and/or to give time for the emission decay process to occur. As such, properties of the electromagnetic radiation 336 can be detected via the light detectors at a moment when the light source is not emitting the light 311. The light source 310 can comprise a 200-700 nm laser diode (e.g., a 405 nm laser diode). Additionally or alternatively, the light source 310 can comprise gallium nitride and/or indium gallium nitride quantum wells.

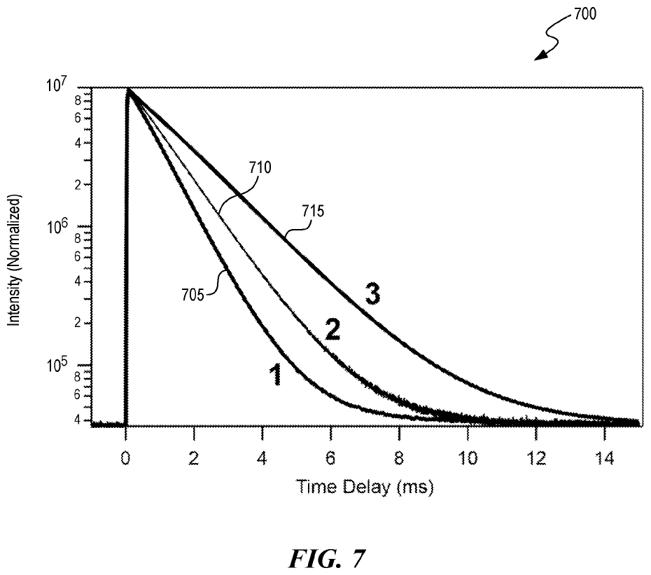

The TRPL detector 315 is configured to measure an intensity of the electromagnetic radiation 336, and/or a change (e.g., a decay) in intensity of the electromagnetic radiation 336 over a time period (e.g., less than 20 ms). For example, as explained in more detail with reference to FIG. 7, the TRPL detector 315, and/or the controller 305 in communication with the TRPL detector 315, can determine changing intensities of the electromagnetic radiation 336 at various times (e.g., 1 ms, 2 ms, 3 ms, etc.) over the time period to produce a PL decay curve. The produced curve can then be fitted against a baseline curve to produce an output indicating how well the produced curve corresponds to the baseline curve. As explained elsewhere herein, in some embodiments the output is used to authenticate the target 303 and/or substrate 330. For example, if the output is within a predetermined range for the target 303, then that target 303 can be authenticated or deemed not unauthentic, and if the output is outside of the predetermined range for the target 303, then the target 303 can be deemed unauthentic.

The SRPL detector 320 is configured to measure a wavelength (e.g., color) and/or PL emission spectrum of the electromagnetic radiation 336 of the target 303 or composite 335. In some embodiments, the SRPL detector 320 can produce an output corresponding to one or more (e.g., two, three, four, etc.) emission maximums of the emission spectra. The measured output, or one or more emission maximums, can be compared to a baseline value, e.g., corresponding to an authenticated target. In some embodiments, the output is used to authenticate the target 303 and/or substrate 330. For example, if the output is within a predetermined range for the target 303, then that target 303 can be authenticated, and if the output is outside of the predetermined range for the target 303, then the target 303 can be deemed unauthentic.

In operation, the light source 310 can emit the light 311 toward the target 303 causing some of the light 311 to be absorbed by the target 303 and the electromagnetic radiation 336 to be emanated away from the target 303 toward the one or more detectors (i.e., the TRPL detector 315 and/or the SRPL detector 320). The TRPL detector 315 and SRPL detector 320 can each obtain independent property data or measurements of the electromagnetic radiation 336, and such data can be used (e.g., by the controller 305) to authenticate the target 303.

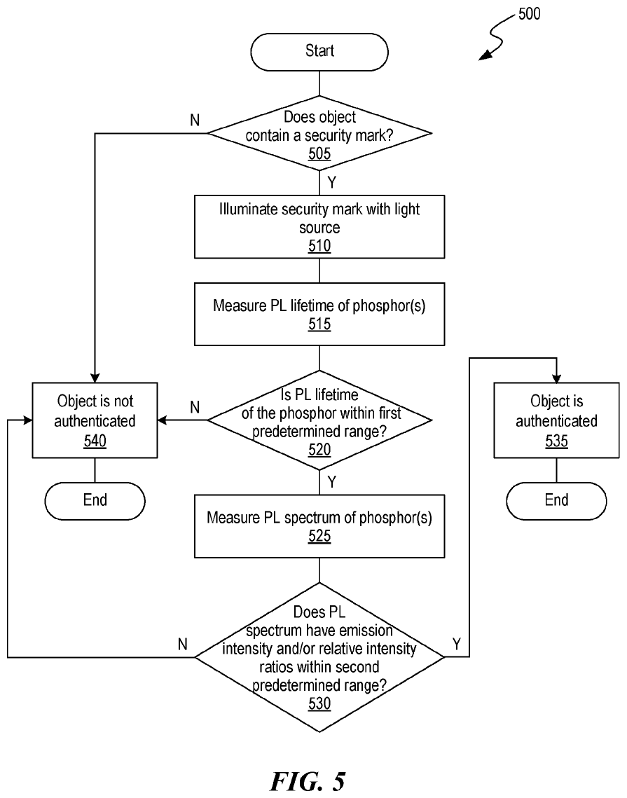

FIG. 4 is a schematic illustration of the system 300 for detecting emitted light from and/or authenticating a target 403, in accordance with embodiments of the present technology. The target 403 includes a substrate 430 (e.g., the substrate 210; FIG. 2), a matrix 437 (e.g., the matrix 205; FIG. 2) embedded in the substrate, and a phosphor 436 (e.g., the phosphor 101; FIGS. 1 and 2) embedded in or attached to the matrix 437.

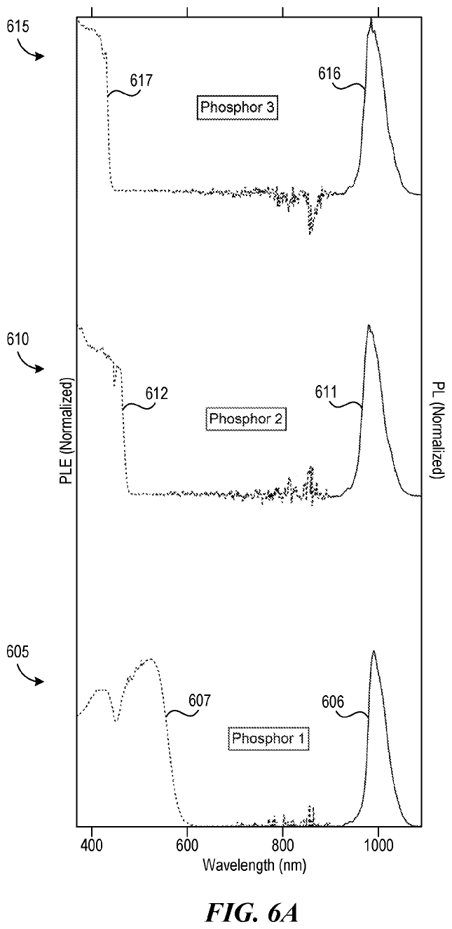

FIG. 5 is a flow chart 500 including a method for authenticating a target (e.g., the target 303/403; FIGS. 3 and 4), in accordance with embodiments of the present technology. The method can include determining whether the object to be authenticated contains a security mark (process portion 505). If the object should but does not include a security mark, the object is not authenticated (process portion 540) and the authentication process can end. In some embodiments, a light detector (e.g., the SRPL detector 320; FIGS. 3 and 4) is used to detect whether the object contains a security mark, e.g., having a wavelength or emission maxima within a particular range (e.g., 800-1200 nm). If the object does contain a security mark, the process can proceed to illuminate the security mark of the target with a light source (e.g., the light source 310; FIGS. 3 and 4) (process portion 510). As previously described, the light source can emit light toward the security mark to cause it, or more particularly the phosphor of the security mark, to emanate electromagnetic radiation away from the security mark.

The process continues by measuring (e.g., via the TRPL detector 315; FIGS. 3 and 4) a PL lifetime or TRPL of the emanated electromagnetic radiation from the phosphor (process portion 515). If the PL lifetime or TRPL of the emanated electromagnetic radiation is not within a first predetermined range, the object is not authenticated (process portion 540) and the authentication process can end. If the PL lifetime or TRPL of the emanated electromagnetic radiation is within the first predetermined range, the process can proceed to measure a PL spectrum or SRPL (e.g., via the SRPL detector 320; FIGS. 3 and 4) of the emanated electromagnetic radiation from the phosphor (process portion 525). If the PL spectrum or SRPL of the electromagnetic radiation has an emission intensity and/or relative intensity ratios outside of a second predetermined range, the object is not authenticated (process portion 540) and the authentication process can end. If the PL spectrum or SRPL of the electromagnetic radiation has an emission intensity and/or relative intensity ratios within the second predetermined range, the object is authenticated and the authentication process can end.

### III. Experimental Results

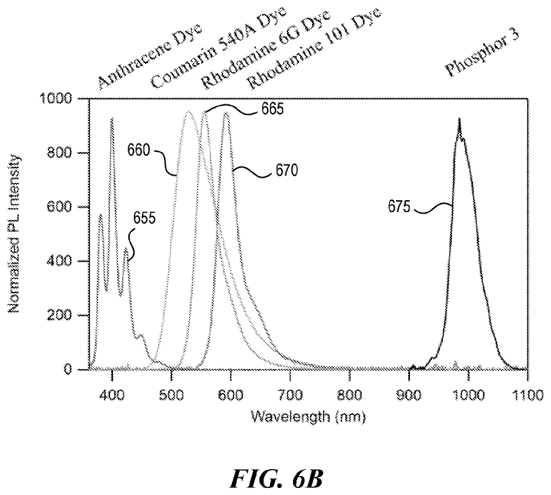

FIG. 6A includes plots 605, 610, 615 illustrating photoluminescence excitation (PLE) spectra (dashed lines) and corresponding photoluminescence (PL) spectra (solid lines) for different phosphor compositions, in accordance with embodiments of the present technology. The PLE spectra corresponds to an absorption spectra and the PL spectra corresponds to a emission spectra. The PLE for each of the plots 605, 610, 615 was monitored at PL peak maximums. Plot 605 includes a PL spectra 606 and PLE spectra 607 for a first phosphor composition (“Phosphor 1”), Plot 610 includes a PL spectra 611 and PLE spectra 612 for a second phosphor composition (“Phosphor 2”), and Plot 615 includes a PL spectra 616 and PLE spectra 617 for a third phosphor composition (“Phosphor 3”). The PL and PLE (i.e., intensity) for each of Phosphor 1, Phosphor 2 and Phosphor 3 is measured for wavelengths up to approximately 1100 nm.

The PL maximums for each of Phosphor 1, Phosphor 2 and Phosphor 3 occurs at a wavelength of about 1000 nm. Advantageously, because the PL maximums for each of Phosphor 1, Phosphor 2 and Phosphor 3 occurs at about the same wavelength (e.g., within 50 nm), the same detector (e.g., the SRPL detector 320; FIGS. 3 and 4) can be used to determine the PL for each of Phosphor 1, Phosphor 2 and Phosphor 3.

The PLE spectra and corresponding PL spectra for each of Phosphor 1, Phosphor 2 and Phosphor 3 exhibit no overlap, and more specifically include a difference of about 500 nm for Phosphor 1, about 650 nm for Phosphor 2, and about 650 nm for Phosphor 3. The difference between the absorption maxima and the emission maxima, or Stokes Shift, enables more better light outcoupling and light to be detected by the light detector(s). Additionally, a larger Stokes shift can enable the PLE and the PL to both not be detected by the human eye, thereby enabling covert marks to be formed. Phosphor 3, for example, having a PLE spectra below 400 nm and a PL spectra above 700 nm is not detectable by the naked eye.

FIG. 6B is a plot 650 illustrating PL spectra of different light emitting materials that include phosphors and dyes, in accordance with embodiments of the present technology. The plot 650 includes PL spectra 655 for Anthracene Dye (“Anthracene spectra 655”) corresponding to a purple dye, PL spectra 660 for Coumarin 540A Dye (“Coumarin spectra 660”) corresponding to a green dye, PL spectra 665 for Rhodamine 6G Dye (“Rhodamine spectra 665”) corresponding to a gold dye, PL spectra 670 for Rhodamine 101 Dye (“Rhodamine spectra 670”) corresponding to a red dye, and PL spectra 675 for Phosphor 3. In practice, the different dyes can be combined to form a plurality of unique PL spectra with different peak intensity ratios that can be used for authentication purposes.

FIG. 7 is a plot 700 illustrating PL decays of the phosphor compositions of FIG. 6A, in accordance with embodiments of the present technology. The plot 700 includes a first decay curve 705 corresponding to Phosphor 1, a second decay curve 710 corresponding to Phosphor 2, and a third decay curve corresponding to Phosphor 3. Each of the first, second, and third decay curves 705, 710, 715 are unique and distinguishable from one another, with Phosphor 1 having a lifetime of about 0.94 ms, Phosphor 2 having a lifetime of about 1.30 ms, and Phosphor 3 having a lifetime of about 1.80 ms. In some embodiments, the first, second, and third decay curves 705, 710, 715 can correspond to the curves described herein that are generated by the TRPL detector (e.g., the TRPL detector 315; FIGS. 3 and 4). The produced curve for a given target can be analyzed relative to a baseline curve to produce an output that can be used to authenticate the target, e.g., based on whether the output is within a predetermined range.

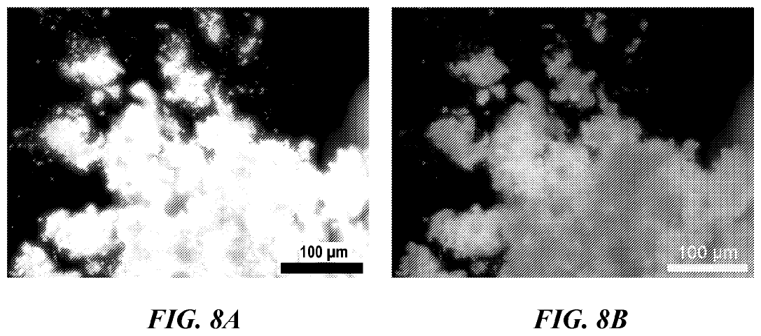

FIG. 8A is a dark-field image of a phosphor composition, and FIG. 8B is a PL image of the phosphor composition of FIG. 8A, in accordance with embodiments of the present technology. The dark-field image of the phosphor composition of FIG. 8A has a yellow color, whereas the PL image of the same phosphor composition in FIG. 8B has emission around 1000 nm (shown as a blue color). The wavelength of the PL image can be detected by a light detector (e.g., the SRPL detector 320; FIGS. 3 and 4) to authenticate an object the phosphor composition is disposed on.

FIGS. 9A-9C illustrate a phosphor composition under different illuminations, in accordance with embodiments of the present technology. More specifically, FIG. 9A illustrates the phosphor composition under room light using a standard camera, FIG. 9B illustrates the phosphor composition under ultraviolet (UV) light using the standard camera, and FIG. 9C illustrates the phosphor composition under UV light using a NIR camera. As shown in FIGS. 9A-9C, the phosphor composition emits a different electromagnetic radiation for each condition, with the room light of FIG. 9A producing a yellow color over a beige backing, FIG. 9B producing a blue color over a blueish backing, and FIG. 9C producing a violet color over a black backing. The violet color represents the NIR emission from the phosphor. The combination of FIGS. 9A-9C illustrate how the phosphor composition can be authenticated by exposing the phosphor composition to different conditions and detecting the emitted light under different conditions.

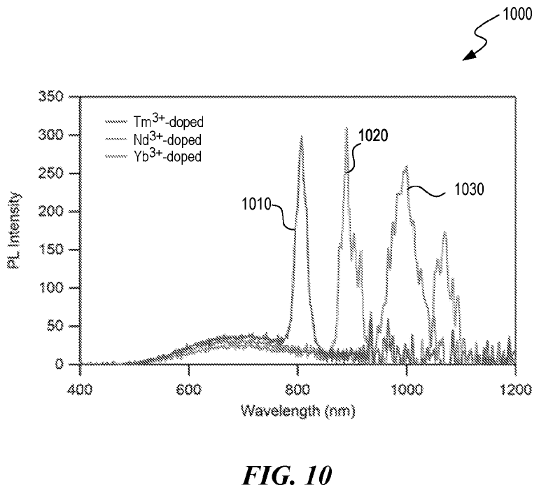

FIG. 10 is a plot 1000 illustrating PL spectra of phosphor compositions including different dopants, in accordance with embodiments of the present technology. The plot 1000 includes PL spectra 1010 for a Tm³⁺-doped phosphor (“Phosphor 4”), PL spectra 1020 for a Nd³⁺-doped phosphor (“Phosphor 5”), and PL spectra 1030 for a Yb³⁺-doped phosphor (“Phosphor 6”), In practice, the different phosphors (e.g., Phosphors 1-3 of FIG. 6A and Phosphors 4-6 of FIG. 10), each have a unique PL spectra, and can be used for authentication purposes with different detectors (e.g., silicon detectors and indium-gallium-arsenide (InGaAs) detectors). For Phosphors 1-3, a semiconductor composition is altered while the dopant remains the same. For Phosphors 4-6, the dopant composition and concentration is altered while the semiconductor composition remains the same.

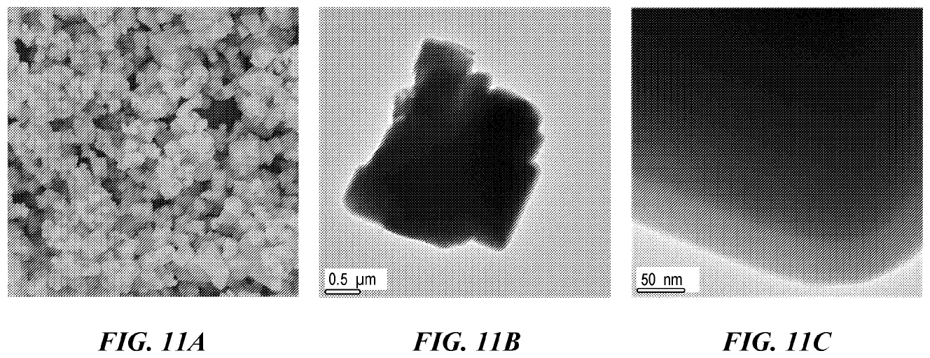

FIG. 11A is a scanning electron microscope (SEM) image of a phosphor composition without a protective shell, and FIGS. 11B and 11C are images of a phosphor composition with a barrier coating (e.g., a protective shell), in accordance with embodiments of the present technology. More specifically, FIG. 11B is a tunneling electron microscope (TEM) image of a single phosphor with a 50-nanometer protective shell (Al₂O₃ coating) at 0.5-micrometer scale and FIG. 11C is a portion of the TEM image of FIG. 11B at a 50-nanometer scale. FIG. 11C illustrates the conformal nature of the Al₂O₃ coating on the phosphor particle.

The barrier coatings, such as those shown in FIGS. 11B and 11C, can be an outermost layer of individual phosphor particles and conform to the underlying surface of the phosphor particle. As noted previously, the barrier coating can comprise silicon dioxide (SiO₂), aluminum dioxide (Al₂O₃), titanium dioxide (TiO₂), and/or hafnium dioxide or hafnium (IV) oxide (HfO₂). In some embodiments, the barrier coatings comprise multiple layers of these materials (e.g., Al2O₃/TiO₂). The barrier coatings can improve the stability of the phosphors towards environmental degradation (e.g., from water and oxygen exposure), and multi-layer coatings can provide enhanced stability. The coatings can be deposited using chemical vapor deposition, atomic layer deposition, or other deposition methods.

### IV. Conclusion

It will be apparent to those having skill in the art that changes may be made to the details of the above-described embodiments without departing from the underlying principles of the present disclosure. In some cases, well known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Throughout this disclosure, the singular terms “a,” “an,” and “the” include plural referents unless the context clearly indicates otherwise. Additionally, the term “comprising,” “including,” and “having” should be interpreted to mean including at least the recited feature(s) such that any greater number of the same feature and/or additional types of other features are not precluded.

Reference herein to “one embodiment,” “an embodiment,” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

Unless otherwise indicated, all numbers expressing wavelengths, concentrations, and other numerical values used in the specification and claims, are to be understood as being modified in all instances by the term “about.” Accordingly, unless indicated to the contrary, the numerical parameters set forth in the following specification and attached claims are approximations that may vary depending upon the desired properties sought to be obtained by the present technology. At the very least, and not as an attempt to limit the application of the doctrine of equivalents to the scope of the claims, each numerical parameter should at least be construed in light of the number of reported significant digits and by applying ordinary rounding techniques. Additionally, all ranges disclosed herein are to be understood to encompass any and all subranges subsumed therein. For example, a range of “1 to 10” includes any and all subranges between (and including) the minimum value of 1 and the maximum value of 10, i.e., any and all subranges having a minimum value of equal to or greater than 1 and a maximum value of equal to or less than 10, e.g., 5.5 to 10.

The disclosure set forth above is not to be interpreted as reflecting an intention that any claim requires more features than those expressly recited in that claim. Rather, as the following claims reflect, inventive aspects lie in a combination of fewer than all features of any single foregoing disclosed embodiment. Thus, the claims following this Detailed Description are hereby expressly incorporated into this Detailed Description, with each claim standing on its own as a separate embodiment. This disclosure includes all permutations of the independent claims with their dependent claims.

The present technology is illustrated, for example, according to various aspects described below as numbered clauses (1, 2, 3, etc.) for convenience. These are provided as examples and do not limit the present technology. It is noted that any of the dependent clauses may be combined in any combination, and placed into a respective independent clause. The other clauses can be presented in a similar manner.

1. A phosphor composition configured to be applied to a physical object, the phosphor composition comprising:

a chemical formula of one of M:ABX₃, M:AB₂X₅, M:A₄BX₆, M:C₂DX₅, OR M:A₂CDX₆ , M:A₈CDX₁₂, M:A₂C₂D₂X₁₀,
wherein—
A is a cation comprising Li⁺, Na⁺, K⁺, Rb⁺, Cs⁺, methylammonium, formamidinium, guanidinium, or mixtures thereof,
B is a cation comprising Pb²⁺, Sn²⁺, Ge²⁺, Cd²⁺, Mg²⁺, Ti²⁺, Hg²⁺ or mixtures thereof,
C is a cation comprising Ag⁺, Cu⁺, Sn⁺, Na⁺, K⁺, Tl⁺, Au+ or mixtures thereof,
D is a cation comprising In³⁺, Bi³⁺, Sb³⁺, Au³⁺ Tl³⁺, or mixtures thereof,
X is an anion comprising O₂₋, S²⁻, Se²⁻, Te²⁻, F⁻, Cl⁻, Br⁻, I⁻ CN⁻ or mixtures thereof, and
M is a cation comprising Y³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Lu³⁺, Sc³⁺, Fe³⁺, Al³⁺, V²⁺, Cr²⁺, Mn²⁺, Bi³⁺ or mixtures thereof.

2. The phosphor composition of any one of the clauses herein, wherein the phosphor composition has an absorption spectra and an emission spectra, and wherein a difference between an absorption maxima of the absorption spectra and an emission maxima of the emission spectra is at least 50 nanometers (nm), 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1000 nm, 1050 nm, 1100 nm, 1150 nm, 1200 nm, or 1250 nm.

3. The phosphor composition of any one of the clauses herein, wherein the phosphor composition has a Stokes shift of at least 50 nanometers (nm), 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1000 nm, 1050 nm, 1100 nm, 1150 nm, 1200 nm, or 1250 nm.

4. The phosphor composition of any one of the clauses herein, wherein the phosphor composition comprises a crystalline lattice, and wherein M is a dopant in the crystalline lattice or on the surface of the crystalline lattice.

5. The phosphor composition of any one of the clauses herein, wherein the phosphor composition comprises a uniform distribution of M.

6. The phosphor composition of any one of the clauses herein, wherein the phosphor composition comprises a crystalline lattice, and wherein M substitutes for B or D in the crystalline lattice or on the surface of the crystalline lattice.

7. The phosphor composition of any one of the clauses herein, wherein M comprises no more than 49% of a molar ratio of M/(B+M) or M/(D+M).

8. The phosphor composition of any one of the clauses herein, wherein the phosphor composition comprises a non-uniform distribution of M.

9. The phosphor composition of any one of the clauses herein, wherein the phosphor composition comprises a crystalline lattice and a cluster of M in the crystalline lattice or on the surface of the crystalline lattice.

10. The phosphor composition of any one of the clauses herein, wherein, when exposed to a light source, the phosphor composition emits electromagnetic radiation from a first portion of the composition and does not emit electromagnetic radiation from a second portion of the phosphor composition different than the first portion.

11. The phosphor composition of any one of the clauses herein, wherein, when exposed to a light source, the composition is configured to emit light having a lower energy than that of the light source.

12. The phosphor composition of any one of the clauses herein, wherein the phosphor composition is configured to absorb light having a wavelength of 250-700 nanometers.

13. The phosphor composition of any one of the clauses herein, wherein, when exposed to a light source, the phosphor composition emits electromagnetic radiation due to band-edge recombination and/or dopant emission.

14. The phosphor composition of any one of the clauses herein, wherein the phosphor composition is amorphous, crystalline, or semicrystalline.

15. The phosphor composition of any one of the clauses herein, wherein the phosphor composition is a powder comprising a mean particle diameter of 1 nanometer-100 micrometers.

16. The phosphor composition of any one of the clauses herein, wherein the phosphor composition comprises a powder, a film, a coating, a pellet, a bead, nanocrystals, or microcrystals.

17. The phosphor composition of any one of the clauses herein, wherein the light emitted by the phosphor composition is undetectable by the human eye.

18. The phosphor composition of any one of the clauses herein, wherein photoluminescence properties of the phosphor composition do not degrade for at least 2, 4, 6, 8, 10, 12, or 14 days.

19. A phosphor composition configured to be applied to a physical object, the phosphor composition comprising an absorption spectra and an emission spectra, and wherein a difference between an absorption maxima of the absorption spectra and an emission maxima of the emission spectra is at least 50 nanometers (nm), 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1000 nm, 1050 nm, 1100 nm, 1150 nm, 1200 nm, or 1250 nm.

20. A phosphor composition configured to be applied to a physical object, the composition comprising a Stokes shift of at least 50 nanometers (nm), 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1000 nm, 1050 nm, 1100 nm, 1150 nm, 1200 nm, or 1250 nm.

21. A method of manufacturing a phosphor composition configured to be applied to a physical object, the method comprising:
forming the phosphor composition of any one of the clauses herein; and
altering the phosphor composition based on a desired application or end use.

22. The method of any one of the clauses herein, wherein altering the phosphor composition is based on a mean particle diameter of the phosphor composition

23. The method of any one of the clauses herein, wherein forming the phosphor composition comprises varying a grinding time and/or a humidity of the phosphor composition.

24. The method of the any one of the clauses herein, wherein altering the phosphor composition comprises sieving, grinding, milling, melting and/or centrifuging the phosphor composition.

25. A composite configured to be integrated in or on a solid material, the composite comprising:
a first composition comprising the phosphor composition of any one of the clauses herein; and
a second composition,
wherein the first composition and the second composition, when combined, form the composite.

26. The composite of any one of the clauses herein, wherein the composite comprises a printed symbol, a stamp, a weave-able thread, or a tag.

27. The composite of any one of the clauses herein, wherein the composite comprises a colloid, a printed ink, a thread, a band, a bead, or a suspension.

28. The composite of any one of the clauses herein, wherein the second composition comprises a polymer, a gel, a colloid, an epoxy, resin, or an inorganic matrix.

29. The composite of any one of the clauses herein, wherein the second composition is a matrix configured to be combined with the first composition.

30. The composite of any one of the clauses herein, wherein, when exposed to light, the first composition emits photoluminescence within a wavelength range, and wherein the second composition, when exposed to the light, does not emit photoluminescence within the wavelength range.

31. The composite of any one of the clauses herein, wherein the ratio of the first composition to the second composition is less than 50%, 40%, 30%, 20%, or 10%.

32. The composite of any one of the clauses herein, wherein the composite is configured to be manipulated into a desired pattern via 2-dimensional (2D) printing, 3D printing, stamping, spraying, spin coating, or extruding.

33. The composite of any one of the clauses herein, wherein the second composition comprises poly(methylmetacrylate) (PMMA), PMMA in a toluene solution, polystyrene (PS), poly(vinyltoluene) (PVT), ethylene vinyl acetate (EVA) and/or poly(dimethylsiloxane) (PDMS).

34. A structure comprising the composite of any one of the clauses herein.

35. A method of forming a composite, the method comprising:
mixing a first composition with a second composition to form a composite, the first composition comprising the phosphor composition of any one of the clauses herein; and
treating the composite to have one or more desired characteristics.

36. The method of any one of the clauses herein, wherein the composite is the composite of any one of the clauses herein.

37. The method of any one of the clauses herein, wherein treating the composite comprises stirring, mixing, heating, annealing, curing, and activating with light or heat.

38. A system for detecting and/or authenticating a composite on a target, the system comprising: a controller;
a light source electrically coupled to and/or controllable by the controller, wherein the light source is configured to emit light toward a target to be authenticated; and
a light detector electrically coupled to and/or controllable by the controller, wherein the light detector is configured to detect electromagnetic radiation emanated from the target in response to the emitted light from the light source, and wherein the light detector is configured to measure time-resolved photoluminescence (TRPL) and/or spectrally-resolved broadband photoluminescence.

39. The system of any one of the clauses herein, wherein the light source comprises a 405 nanometer (nm) laser diode.

40. The system of any one of the clauses herein, wherein the light source comprises a 200-1000 nanometer (nm) laser diode.

41. The system of any one of the clauses herein, wherein the light source is configured to emit a pulsed light.

42. The system of any one of the clauses herein, wherein the light source comprises gallium nitride or indium gallium nitride quantum wells.

43. The system of any one of the clauses herein, wherein the light detector comprises a TRPL detector.

44. The system of any one of the clauses herein, wherein the light detector comprises silicon, germanium, indium phosphide, gallium arsenide, or indium gallium arsenide.

45. The system of any one of the clauses herein, wherein the light detector comprises a semiconductor material with a bandgap configured to absorb the emitted light.

46. The system of any one of the clauses herein, wherein the light detector and/or controller is configured to measure a wavelength of the electromagnetic radiation emanated from the target.

47. The system of any one of the clauses herein, wherein the light detector and/or controller is configured to measure an absolute intensity of the electromagnetic radiation emanated from the target.

48. The system of any one of the clauses herein, wherein the controller is configured to obtain an absorbed light of the target, and wherein the light detector and/or controller is configured to measure an intensity of the electromagnetic radiation from the target relative to the obtained absorbed light.

49. The system of any one of the clauses herein, wherein the light detector and/or the controller is configured to detect a relative intensity ratio of multiple wavelengths of the electromagnetic radiation emanated from the target.

50. The system of any one of the clauses herein, wherein the light detector and/or the controller is configured to detect a decay of an intensity over time of the electromagnetic radiation emanated from the target.

51. The system of any one of the clauses herein, wherein the light detector and/or the controller is configured to detect a lifetime of an emission event from a phosphor of the target.

52. The system of any one of the clauses herein, wherein the light detector is configured to obtain an image of the target or a mark on the target.

53. The system of any one of the clauses herein, wherein the light detector and/or controller is not configured to obtain an image of the target or a mark on the target to authenticate the target.

54. The system of any one of the clauses herein, wherein:
the light detector and/or controller is configured to compare the detected electromagnetic radiation to one or more identifiers, and
the identifiers are stored on an external network in communication with the controller.

55. The system of any one of the clauses herein, wherein the light detector and/or controller is configured to compare the detected photoluminescence to one or more identifiers stored locally on the system.

56. The system of any one of the clauses herein, wherein the light detector a first light detector, the system further comprising a second light detector electrically coupled to and/or controllable by the controller.

57. The system of any one of the clauses herein, wherein the light detector is a first light detector comprising a time-resolved photoluminescence detector configured to measure of photoluminescence lifetime of a phosphor of the target, the system further comprising a second light detector electrically coupled to and/or controllable by the controller, wherein the second light detector is a spectrally-resolved broadband photoluminescence detector configured to measure a photoluminescence spectral intensity of the phosphor of the target.

58. The system of any one of the clauses herein, further comprising a filter configured to filter the light detected by the light detector.

59. A method of detecting and/or authenticating a composite on a material, the method comprising:
causing light to be emitted from a light source toward a mark on a target;
measuring, via a detector, photoluminescence properties emanated from the mark in response to the light emitted from the light source; and
based on the measured photoluminescence properties, determining whether the mark is authentic.

60. The method of any one of the clauses herein, wherein measuring the photoluminescence properties comprises measuring a photoluminescence lifetime of a phosphor of the mark.

61. The method of any one of the clauses herein, wherein the detector is a time-resolved detector, and wherein measuring the photoluminescence properties comprises measuring a photoluminescence lifetime of a phosphor of the mark.

62. The method of any one of the clauses herein, wherein measuring the luminescence properties comprises measuring a photoluminescence spectrum of a phosphor of the mark.

63. The method of any one of the clauses herein, wherein the detector is a broadband photoluminescence detector, and wherein measuring the photoluminescence properties comprises measuring a photoluminescence spectrum of a phosphor of the mark.

64. The method of any one of the clauses herein, wherein the detector is a time-resolved detector, and wherein measuring the photoluminescence properties comprises measuring a photoluminescence lifetime of a phosphor of the mark, the method further comprising measuring, via a broadband photoluminescence detector, a photoluminescence spectrum of the phosphor of the mark.

65. The method of any one of the clauses herein, wherein determining whether the mark is authentic comprises determining whether a photoluminescence spectrum of the phosphor of the mark has an emission intensity within a predetermined range.

66. The method of any one of the clauses herein, wherein determining whether the mark is authentic comprises determining whether a photoluminescence spectrum of the phosphor of the mark has a relatively intensity ratio within a predetermined range.

1. A phosphor composition configured to be applied to a physical object, the phosphor composition comprising:
a chemical formula of one of M:ABX3, M:AB2X5, M:A4BX6, M:C2DX5, or M:A2CDX6, M:A8CDX12, or M:A₂C₂D₂X₁₀,
wherein:
A is a cation comprising lithium (Li⁺), sodium (Na⁺), potassium (K⁺), rubidium (Rb⁺), caesium (Cs⁺), methylammonium, formamidinium, guanidinium, or mixtures thereof,
B is a cation comprising lead (Pb²⁺), tin (Sn²⁺), germanium (Ge²⁺), cadmium (Cd²⁺), magnesium (Mg²⁺), titanium (Ti²⁺), mercury (Hg²⁺) or mixtures thereof,
C is a cation comprising silver (Ag⁺), copper (Cu⁺), tin (Sn⁺), sodium (Na⁺), potassium (K⁺), thallium (Tl⁺), gold (Au⁺) or mixtures thereof,
D is a cation comprising indium (In³⁺), bismuth (Bi³⁺), antimony (Sb³⁺), gold (Au³⁺), thallium (Tl³⁺) or mixtures thereof,
X is an anion comprising oxygen (O²⁻), sulfur (S²⁻), Selenium (Se²⁻), tellurium (Te²⁻), fluorine (F−), chlorine (Cl−), bromine (Br−), iodine (I−), cyanide (CN−) or mixtures thereof, and
M is a cation comprising yttrium (Y³⁺), Lanthanum (La³⁺), cerium (Ce³⁺), praseodymium (Pr³⁺), neodymium (Nd³⁺), promethium (Pm³⁺), samarium (Sm³⁺), europium (Eu³⁺), gadolinium (Gd³⁺), terbium (Tb³⁺), dysprosium (Dy³⁺), holmium (Ho³⁺), erbium (Er³⁺), thulium (Tm³⁺), ytterbium (Yb³⁺), lutetium (Lu³⁺), scandium (Sc³⁺), iron (Fe³⁺), aluminum (Al³⁺), vanadium (V²⁺), chromium (Cr²⁺), manganese (Mn²⁺), bismuth (Bi³⁺) or mixtures thereof.

2. The phosphor composition of claim 1, wherein the chemical formula comprises M:ABX₃ or M:A₂CDX₆, and wherein M comprises ytterbium, erbium, thulium, or neodymium.

3. The phosphor composition of claim 1, wherein the chemical formula comprises (i) M:CsPbX, (ii) M:Cs₂AgBiX₆, or (iii) M:Cs₂Ag₁₋ₓNaₓBi_{1-y}In_{y}Br₆.

4. The phosphor composition of claim 1, wherein the phosphor composition has an absorption spectra and an emission spectra, and wherein a difference between an absorption maxima of the absorption spectra and an emission maxima of the emission spectra is within a range of 150 nanometers (nm) to 1250 nm.

5. The phosphor composition of claim 1, wherein the phosphor composition has a Stokes shift of at least 50 nanometers.

6. The phosphor composition of claim 1, wherein the phosphor composition comprises a crystalline lattice, and wherein M is a dopant in the crystalline lattice or on the surface of the crystalline lattice.

7. The phosphor composition of claim 1, wherein M comprises no more than 49% of a molar ratio of M/(B+M) or M/(D+M).

8. The phosphor composition of claim 1, wherein, when exposed to a light source, the phosphor composition emits electromagnetic radiation from a first portion of the composition and does not emit electromagnetic radiation from a second portion of the phosphor composition.

9. The phosphor composition of claim 1, wherein, when exposed to a light source, the phosphor composition is configured to emit light having a lower energy than that of the light source.

10. The phosphor composition of claim 1, wherein the phosphor composition is configured to absorb light having a wavelength of 250-700 nanometers.

11. The phosphor composition of claim 1, wherein the phosphor composition is a powder comprising a mean particle diameter of 1 nanometer-100 micrometers.

12. The phosphor composition of claim 1, wherein the light emitted by the phosphor composition is undetectable by the human eye.

13. The phosphor composition of claim 1, further comprising a coating comprising silicon dioxide (SiO₂), aluminum dioxide (Al₂O₃), titanium dioxide (TiO₂), and/or hafnium dioxide (HfO₂).

14. A composite configured to be integrated in or on a solid material, the composite comprising:
a first composition comprising a chemical formula of one of M:ABX₃, M:AB₂X₅, M:A₄BX₆, M:C₂DX₅, or M:A₂CDX₆, M:A₈CDX₁₂, M:A₂C₂D₂X₁₀,
wherein:
A is a cation comprising lithium (Li⁺), sodium (Na⁺), potassium (K⁺), rubidium (Rb⁺), caesium (Cs⁺), methylammonium, formamidinium, guanidinium, or mixtures thereof,
B is a cation comprising lead (Pb²⁺), tin (Sn²⁺), germanium (Ge²⁺), cadmium (Cd²⁺), magnesium (Mg²⁺), titanium (Ti²⁺), mercury (Hg²⁺) or mixtures thereof,
C is a cation comprising silver (Ag⁺), copper (Cu⁺), tin (Sn⁺), sodium (Na⁺), potassium (K⁺), thallium (Tl⁺), gold (Au⁺) or mixtures thereof,
D is a cation comprising indium (In³⁺), bismuth (Bi³⁺), antimony (Sb³⁺), gold (Au³⁺), thallium (Tl³⁺) or mixtures thereof,
X is an anion comprising oxygen (O₂₋), sulfur (S²⁻), Selenium (Se²⁻), tellurium (Te²⁻), fluorine (F−), chlorine (Cl−), bromine (Br−), iodine (I−), cyanide (CN−) or mixtures thereof, and
M is a cation comprising yttrium (Y³⁺), Lanthanum (La³⁺), cerium (Ce³⁺), praseodymium (Pr³⁺), neodymium (Nd³⁺), promethium (Pm³⁺), samarium (Sm³⁺), europium (Eu³⁺), gadolinium (Gd³⁺), terbium (Tb³⁺), dysprosium (Dy³⁺), holmium (Ho³⁺), erbium (Er³⁺), thulium (Tm³⁺), ytterbium (Yb³⁺), lutetium (Lu³⁺), scandium (Sc³⁺), iron (Fe³⁺), aluminum (Al³⁺), vanadium (V²⁺), chromium (Cr²⁺), manganese (Mn²⁺), bismuth (Bi³⁺) or mixtures thereof; and
a second composition, wherein the first composition and the second composition, when combined, form the composite.

15. The composite of claim 14, wherein the composite comprises at least one of
(a) a printed symbol, a stamp, a weave-able thread, or a tag; or
(b) a colloid, a printed ink, a thread, a band, a bead, or a suspension.

16. The composite of claim 14, wherein the second composition comprises a polymer, a gel, a colloid, an epoxy, resin, or an inorganic matrix.

17. The composite of claim 14, wherein the second composition comprises poly(methylmetacrylate) (PMMA), PMMA in a toluene solution, polystyrene (PS), poly(vinyltoluene) (PVT), ethylene vinyl acetate (EVA) and/or poly(dimethylsiloxane) (PDMS).

18. The composite of claim 14, wherein, when exposed to light, the first composition emits photoluminescence within a wavelength range, and wherein the second composition, when exposed to the light, does not emit photoluminescence within the wavelength range.

19. The composite of any one of claim 14, wherein the ratio of the first composition to the second composition is less than 50%, 40%, 30%, 20%, or 10%.

20. A system for detecting and/or authenticating a composite on a target, the system comprising:
a controller;
a light source electrically coupled to and/or controllable by the controller, wherein the light source is configured to emit light toward a target to be authenticated; and
a light detector electrically coupled to and/or controllable by the controller, wherein the light detector is configured to detect electromagnetic radiation emanated from the target in response to the emitted light from the light source, and wherein the light detector is configured to measure time-resolved photoluminescence (TRPL) and/or spectrally-resolved broadband photoluminescence.

21. The system of claim 20, wherein the light source comprises a 200-1000 nanometer (nm) laser diode and/or gallium nitride or indium gallium nitride quantum wells.

22. The system of claim 20, wherein the light detector comprises:
a TRPL detector;
silicon, germanium, indium phosphide, gallium arsenide, or indium gallium arsenide; or
a semiconductor material with a bandgap configured to absorb the emitted light.

23. The system of claim 20, wherein the light detector and/or the controller is configured to measure an absolute intensity of the electromagnetic radiation emanated from the target.

24. The system of claim 20, wherein the controller is configured to obtain an absorbed light of the target, and wherein the light detector and/or the controller is configured to measure an intensity of the electromagnetic radiation from the target relative to the obtained absorbed light.

25. The system of claim 20, wherein the light detector and/or the controller is configured to detect at least one of (i) a relative intensity ratio of multiple wavelengths of the electromagnetic radiation emanated from the target, (i) a decay of an intensity over time of the electromagnetic radiation emanated from the target, or (iii) a lifetime of an emission event from a phosphor of the target.

26. The system of claim 20, wherein the light detector and/or controller is configured to obtain an image of the target or a mark on the target to authenticate the target.

27. The system of claim 20, wherein the light detector is a first light detector comprising a time-resolved photoluminescence detector configured to measure of photoluminescence lifetime of a phosphor of the target, the system further comprising a second light detector electrically coupled to and/or controllable by the controller, wherein the second light detector is a spectrally-resolved broadband photoluminescence detector configured to measure a photoluminescence spectral intensity of the phosphor of the target.
